(19) United States
(12) Patent Application Publication
(10) Pub. No.: US 2019/0113469 A1
(43) Pub. Date: Apr. 18, 2019

(54) ANGLED BEAM INSPECTION SYSTEM FOR SEMICONDUCTOR DEVICES

(71) Applicant: GLOBALFOUNDRIES INC., GRAND CAYMAN (KY)

(72) Inventors: Oliver D. Patterson, Poughkeepsie, NY (US); Richard F. Hafer, Sherman, CT (US); Dave M. Salvador, Beacon, NY (US); Yue Ke, Fishkill, NY (US)

(73) Assignee: GLOBALFOUNDRIES INC., GRAND CAYMAN (KY)

(21) Appl. No.: 15/786,986

(22) Filed: Oct. 18, 2017

(51) Int. Cl. G01N 23/22; H01J 37/21; G01N 23/225; H01J 37/20

(52) U.S. Cl. CPC G01N 23/2206; H01J 37/21; G01N 23/2251; G01N 2223/6462; H01J 2237/202; G01N 2223/6116; H01J 37/20

(57) ABSTRACT

A method of inspecting semiconductors and a semiconductor inspection system are disclosed. In an embodiment, the method comprises directing a charged particle beam onto a semiconductor device at an angle in a range between five degrees and eighty-five degrees from a normal to a top surface of the semiconductor; scanning the particle beam across a field of the semiconductor device; adjusting the semiconductor to maintain the particle beam at a defined focus on the semiconductor while scanning the particle beam across the field of the semiconductor device; detecting secondary and backscattered electrons from the semiconductor; and processing the detected secondary and backscattered electrons to inspect for defined conditions of the semiconductor. In an embodiment, the particle beam is maintained at the defined focus on the semiconductor device by controlling the position of the semiconductor device relative to a beam emitter that emits the particle beam.

### BACKGROUND

This invention generally relates to inspecting semiconductor devices, and more specifically, to methods and systems in which a charged particle beam such as an electron or ion beam is used to inspect the semiconductor devices.

Semiconductor devices are widely used in the electronics industry because of their small size, multi-function capabilities, and low manufacturing costs. Semiconductor devices may be fabricated by various manufacturing processes, such as a photolithography process, an etching process, and a deposition process. These semiconductor devices usually include a large number of components such as CMOS transistors, DRAMS, and other structures.

Semiconductor devices are typically inspected for flaws or defects. The inspection can be done to improve the fabrication process and to identify flaws in the semiconductor devices. Many different types of inspection tools have been developed for the inspection of semiconductor wafers. Defect inspection is currently performed using techniques such as bright field imaging, dark field imaging, and electron beam imaging.

In order to reduce the size of CMOS transistors further, the semiconductor industry is moving to three dimensional gates called FINFETs or TRIGATEs. These structures are susceptible to new defect types that are manifest in the height dimension. Two examples of such defect types are incorrect fin and gate height. These defects are not visible with top-down imaging.

### SUMMARY

Embodiments of the invention provide a method of inspecting semiconductors, and a semiconductor inspection system. In an embodiment, the method comprises directing a charged particle beam onto a semiconductor device at an angle in a range between five degrees and eighty-five degrees from a normal to a top surface of the semiconductor device, wherein secondary and backscattered electrons are transmitted from the semiconductor device; scanning the charged particle beam across a specified field of the semiconductor device; adjusting the semiconductor device to maintain the charged particle beam at a defined focus on the semiconductor device while scanning the charged particle beam across the specified field of the semiconductor device; detecting said secondary and backscattered electrons; and processing said detected secondary and backscattered electrons to inspect for defined conditions of the semiconductor device.

In an embodiment, the semiconductor inspection system comprises a stage for holding a semiconductor device; a stage support to move the stage within a defined range of positions; and a beam emitter to direct a charged particle beam onto the semiconductor device at an angle in a range between five degrees and eighty-five degrees from a normal to a top surface of the semiconductor device, wherein secondary and backscattered electrons are transmitted from the semiconductor device. The inspection system further comprises a detector to detect said secondary and backscattered electrons; a processing system to process said detected secondary and backscattered electrons to inspect for defined conditions of the semiconductor device; and a control system for controlling the beam emitter to scan the charged particle beam across a specified field of the semiconductor device, and for adjusting the semiconductor device to maintain the charged particle beam at a defined focus on the semiconductor device while scanning the charged particle beam across the specified field of the semiconductor device.

As mentioned above, in order to reduce the size of CMOS transistors further, the semiconductor industry is moving to three dimensional gates called FINFETs or TRIGATEs. These structures are susceptible to new defect types that are manifest in the height dimension. Two examples of such defect types are incorrect fin and gate height. These defects are not visible with top-down imaging. In addition, other defect types such as sidewall residue may be better detected from an angle rather than from top-down imaging.

Current optical and e-beam inspection tools only inspect directly down (ninety degrees from the plane of the wafer surface). To detect a fin or gate height issue, random in-line cross sections are typically used. Some review SEMs come with a detector at an angle capability in addition to a top down detector. The surface of the wafer could be manually reviewed to look for fin or gate height issues also. A third path is to detect the problem with in-line test and then subsequent failure analysis. This path takes much more time.

A large area high resolution inspection technique for detecting fin and gate height issues is urgently needed.

Embodiments of the invention offer solutions for keeping a large field of view (FOV) suitable for e-beam inspection in focus when inspecting a wafer at an angle. For a small FOV like that used for a review SEM (2 um×2 um), when inspecting the wafer at an angle, the working distance from the emitter to the wafer does not change much from the nearest shape in the FOV to the furthest shape in the FOV and the whole FOV is in focus. For a large field of view, such as 60 um×60 um, however, much of the field of view will be out of focus when an angled e-beam is used for inspection. A large FOV is important for inspection because moving the stage takes considerable time. Reducing the number of stage moves increases throughput.

### BRIEF DESCRIPTION OF THE SEVERAL VIEWS OF THE DRAWINGS

FIG. 1 is a diagram of a prior art system for inspecting semiconductor devices.

FIG. 2 illustrates a defect of interest in a semiconductor wafer.

FIG. 3 is a simplified schematic view of a system for inspecting semiconductor devices in accordance with an embodiment of this invention.

FIG. 4 shows a typical path for a raster scan in the inspection of a semiconductor device.

FIG. 5 illustrates moving a semiconductor device being inspected to keep constant a specified horizontal distance in accordance with embodiments of the invention.

FIG. 6 illustrates moving a semiconductor device being inspected to keep constant a working distance of the emitter beam in accordance with embodiments of the invention.

### DETAILED DESCRIPTION

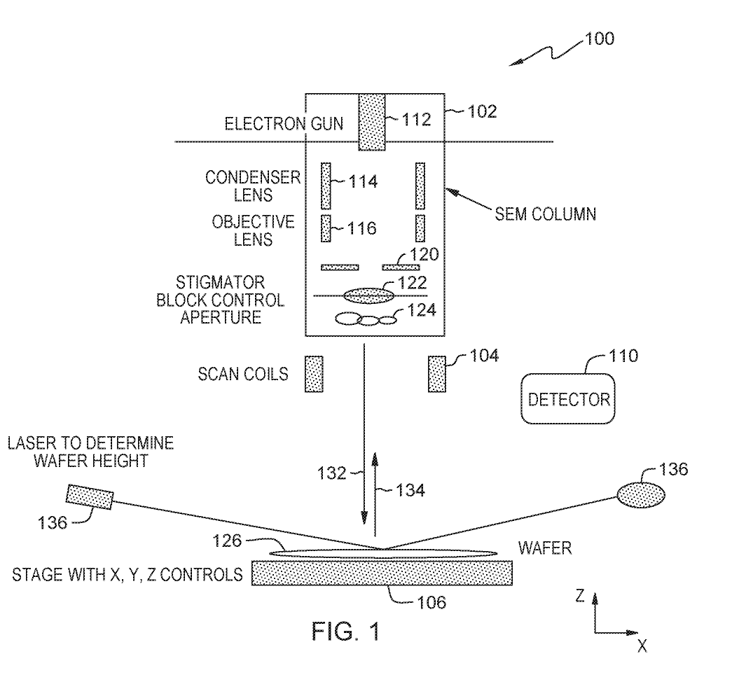

FIG. 1 shows components of a prior art system 100 for inspecting semiconductor wafers. Generally, system 100 comprises a scanning electron microscope (SEM) column 102, scan coils 104, wafer stage 106, and detector 110. SEC column 102, in turn, includes electron gun 112, condenser lens 114, objective lens 116, a stigmator 120, block control 122, and aperture 124. FIG. 1 also shows a wafer 126 on stage 106, a beam 132 generated by SEM 102, a secondary beam 134 transmitted from the wafer, and a pair of lasers 136 for determining the wafer height.

An x, y, z coordinate system may be defined for inspection system 100. In this coordinate system, the Z direction is normal to the wafer surface, the X direction is in the direction the SEM column is pointing along the wafer surface, and the Y coordinate is orthogonal to the X and Z coordinates.

In the operation of system 100, the objective lenses 116 focus the beam 132 to a point on the wafer surface, and the stigmator 120 gives the beam a round shape. Block control 122 blocks out the beam 132 when the stage 106 is moved. The aperture 124 is a plate with different size holes in it, and a particular hole is selected for each wafer or type of wafer. The smaller the hole, the less electrons get through the aperture. This is used to control the beam current. The focus of the beam 132 is achieved primarily by adjusting the stage height.

The electron detector 110 can be directly above the wafer 126, with a hole in the detector to let the incident beam 132 through the detector, or the detector can be off to the side of the wafer. Because the detector has a positive charge, the detector will attract the secondary electrons 134 to wherever the detector is located. The system 100 is capable of detection in physical defect mode (low beam current), voltage contrast mode (high beam currents), and material contrast mode (high landing energy and high negative Wehnelt plate voltage) where only back-scattered electrons are detected.

As mentioned above, current optical and e-beam inspection tools only inspect directly down (ninety degrees from the plane of the wafer surface). These inspection tools and systems are not particularly effective at detecting defect types that are manifest in the height dimension. Such defects may be present on three dimensional gates called FINFETs or TRIGATEs, which are being used in an increasing frequency in the semiconductor industry.

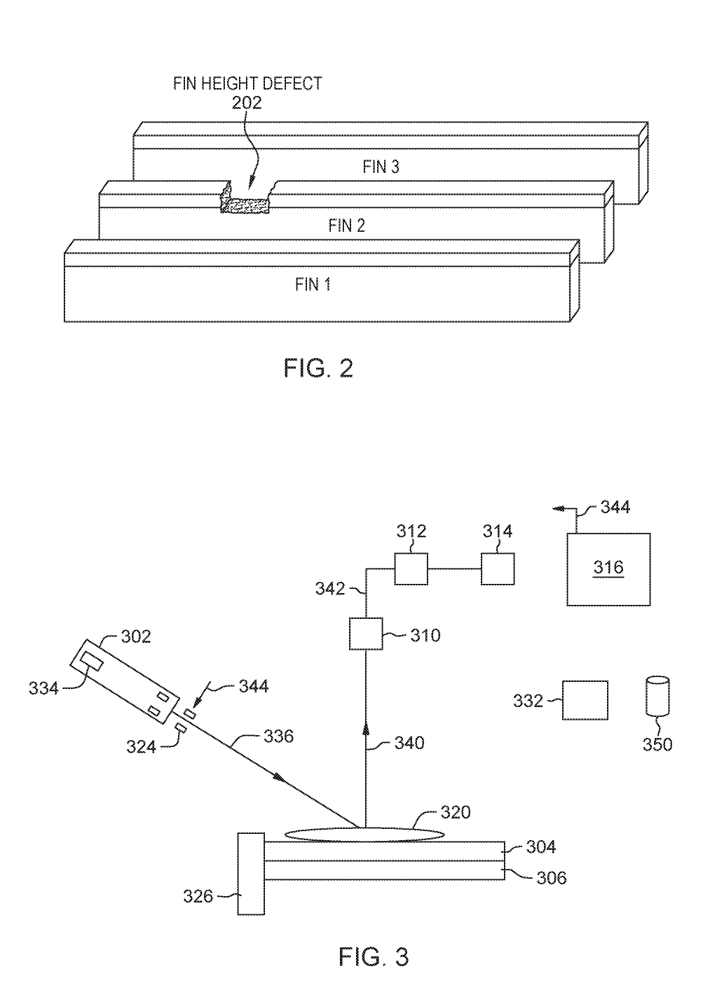

For example, FIG. 2 shows a FIN having a defect 202. Defects of this type may be hard to detect.

Embodiments of the invention address this issue, and more specifically, embodiments of the invention provide methods and systems that are particularly well suited for detecting defect types that are manifest in the height dimension.

Generally, embodiments of the invention use an angled beam emitter to inspect the wafer surface. The stage voltage or position is adjusted to compensate for the change in distance from the emitter to the wafer surface.

FIG. 3 illustrates an inspection system 300 in accordance with an embodiment of the invention. Generally, system 300 includes scanning electron microscope (SEM) column 302, wafer stage 304, stage translation mechanism 306, electron detector 310, processing system 312, image generation unit 314, and control system 316. FIG. 3 also shows a wafer 320 on stage 304, magnetic deflecting coils 324, stage control 326, and a user input-output device 332, which in this embodiment includes a computer.

An electron gun 334 is arranged in SEM 302; and, in operation, the electron gun emits an electron beam 336. The beam emitted from the electron gun is converged by an electron lens and irradiates a portion of the surface of the wafer 320. As a result, a secondary signal 340, including reflected electrons and secondary electrons emitted from the wafer, is generated from the positions of the wafer irradiated with the electron beam 336. The secondary signal is detected by electron detector 310 and is converted into an intensity signal 342 representing the intensity of the secondary signal.

The beam emitter (SEM column) 302 is positioned to emit the charged particle beam 336 onto the wafer 320 at an angle from a normal to a top surface of the wafer. In an embodiment, the beam emitter is positioned to emit the charged particle beam onto the wafer at an angle, in a range between five degrees and eighty-five degrees, to the normal to the top surface of the wafer. In another embodiment, the beam emitter is positioned to emit the charged particle beam at an angle in a range between five degrees and forty-five degrees to the normal to the top surface of the wafer. In another embodiment, the beam emitter is positioned to emit the charged particle beam at an angle in a range between ten degrees and forty-five degrees to the normal to the top surface of the wafer. The beam emitter 302 may be supported in system 300 in any suitable way by any suitable mechanism or support structure to position the beam emitter in this range of angles.

As described above, inspection system 300 uses an electron microscope for inspection of a wafer sample 320. As will be understood by those of ordinary skill in the art, embodiments of the invention may also use other charged particle beams such as an ion beam for inspecting the wafer sample.

From detector 310, intensity signal 342 is provided to processing unit 312, which converts the intensity signal into a digital signal, and applies this digital signal to an image generation unit 314. Unit 314 generates an image of the area of the wafer being inspected, and the image data generated by unit 314 may be used to identify flaws or defects in, or other conditions of, the wafer being inspected.

As illustrated in FIG. 3, wafer 320 is mounted on a sample table 304, and the position of the sample table with respect to the electron beam 336 can be adjusted by drive control device 326. Drive control 326 may be used to move the table 304 in the X and Y directions; and in embodiments of the invention, the drive control may also be used to tilt the table and the wafer 320. This drive control allows the region of the wafer that is irradiated with the electron beam 336 to be moved across the wafer.

In the operation of system 300, electron beam 336 is deflected in a controlled manner by a deflecting magnetic field generated by a deflecting magnet 324 to scan the electron beam across a field, or care area, of the wafer. This deflecting magnet and the magnetic field generated by the magnet are controlled by a control signal 344, generated by control system 316. This deflection control is used to raster-scan the position on the sample wafer 320 that is irradiated with the electron beam.

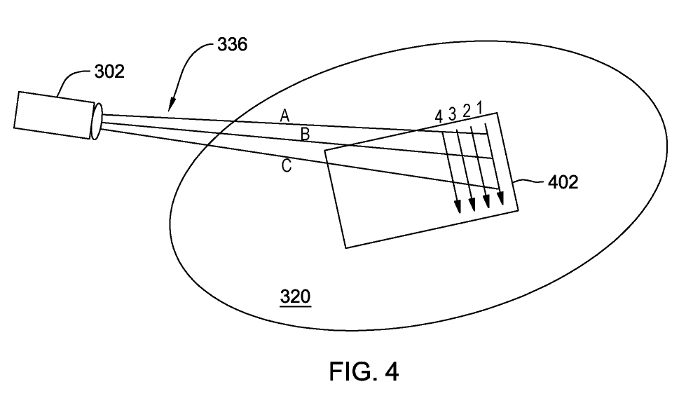

A typical path for the raster-scan is shown in FIG. 4. The beam 336 starts at the one corner of the region 402 being scanned, and the beam scans along vector 1 in steps corresponding to the pixel size. The beam 336 irradiates the first pixel and all emissions from the wafer collected by the collector 310 are assigned to that pixel. At the end of vector 1, the beam 336 is blanked by a block control and re-positions to the beginning of vector 2. The block control is opened and vector 2 is scanned in a similar manner. Vectors 3 and 4 and additional vectors as necessary to image the entire region 402 are scanned next.

Control system 316 controls the inspection and imaging of the wafer in system 300. The control system communicates with the electron microscope 302, stage drive control 326, processing unit 312, and image generating unit 314 to exchange data needed for the inspection and imaging of the wafer 320.

Computer 332 is provided to process data and to receive data from and to output data to a user. The user inputs information through the computer terminal, and this information may be used to control or to adjust operations of the SEM 302, processing system 312, and the overall control system 316. Computer may also be used to display images and data to the user. A secondary storage device 350 may be provided to store data.

Inspection of a wafer surface from an angle, as described above, using an e-beam presents a number of unique challenges. One of these challenges is that shadowing may occur. With e-beam inspection, the beam is rastered in the Y direction while the stage moves in the X direction (continuous scan tools), and sometimes the beam is rastered in both the X and Y directions (leap and scan and hot spot tools). This is because moving the beam is much faster than moving the wafer. As a result of this movement of the beam and the stage, when the e-beam is at an angle to the wafer, shadowing will occur. Shadowing refers to the effect that one fin may block a line of sight—that is, the line of the angled e-beam—to a second fin.

This challenge may be addressed in a number of ways. One approach is to always move the wafer in a direction orthogonal to the lines of the wafer of most interest. The lines of most interest could be, for example, the lines of the fins, as shown in FIG. 2, if the wafer is inspected after fin formation. The lines of most interest can also be gate lines if the wafer is inspected after gate formation. The result will be the largest amount of the wafer lines will be visible, for any one angle between the e-beam and the wafer.

With an angled e-beam, the amount of the shadowing increases the further away from normal the emitter 302 is. A solution to address this is to operate the emitter 302 in the range from five degrees from normal to forty-five degrees from normal. In embodiments of the invention, different angles are appropriate based on the aspect ratio of the line trenches of interest. In embodiments of the invention, the scan is at the minimum angle from the normal needed to detect the defect of interest. With reference to FIG. 2, if the fin height is x nm and the space between fins is x nm, then a forty-five degree scan angle would allow the bottom of Fin 2 to be visible to the e-beam—that is, the e-beam would be able to scan across the bottom of Fin 2. A scan angle of thirty degrees would, in embodiments of the invention, be better.

Another challenge is that as the e-beam moves across the wafer, the distance from the emitter 302 to the specific area on the wafer surface on which the e-beam is directed varies if the wafer 320 is not moving. This distance is referred to as the working distance (w—defined as the distance from the final lens of the electron column to the wafer surface) and is a function of the height (z) of the emitter above the wafer surface, and the horizontal offset (x) from the final lens of the electron column to the wafer location being scanned. As this distance w varies, the wafer will go out of focus from the front to the back of the field of view (FOV). For maximum throughput, a priority for e-beam inspection, a FOV as large as possible should be scanned. This is because each leap of the waver takes substantial time. FOVs of 70 um×70 um are realistic for top-down inspection systems.

In embodiments of the invention, wafer 320 is adjusted to maintain the e-beam 336 in focus on the wafer while scanning the e-beam across the field of view. In embodiments of the invention, the desired or defined focus is maintained by adjusting the position of the wafer, and in other embodiments of the invention, the desired or defined focus is maintained by adjusting the chuck voltage of the wafer stage 304.

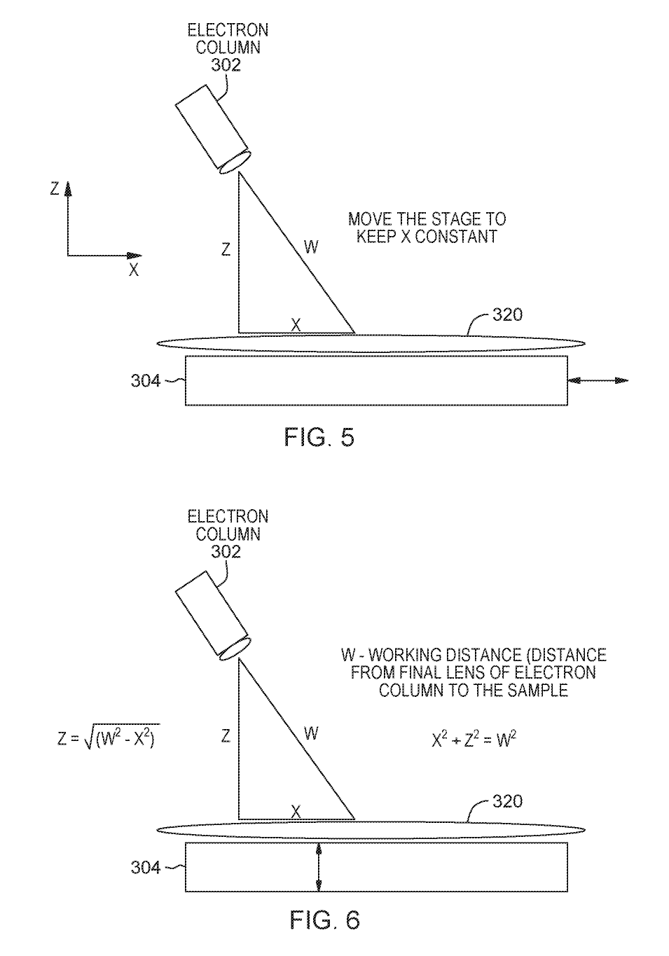

With reference to FIG. 5, one solution is to move the wafer in the X direction as the wafer is rastered to keep w constant. In this solution, instead of scanning through the full field of view range, the focus of the e-beam will be fixed but the area being scanned will be controlled by the moving wafer. In this solution, the working distance w does not change and so the wafer stays in focus without adjusting the focus settings of the electron gun 302. This is particularly appropriate for continuous scan mode. Another option would be to keep x constant and allow z to vary slightly as the beam rasters in the lateral direction.

With reference to FIG. 6, another solution is to adjust the z height of the emitter 302 relative to the wafer 320. As indicated above, the working distance (w) is a function of the height (z) of the emitter above the wafer surface and the horizontal offset (x) from the final lens of the column to the waver location being scanned. During the scan, the z can be adjusted by raising or lowering the wafer stage 304 to adjust z, keeping w constant, using z=sqrt (w²−x²−y²). Another option is to adjust z based on the raster row, to keep w constant according to the equation: Z=sqrt (w²−x²). In this solution, the wafer moves up/down, instead of left/right.

In the above-discussed solutions, the desired movement of the wafer and wafer stage can be pre programmed into control 316 so that the movement of the wafer stage is coordinated in the desired way with the scanning of the e-beam 336 across the wafer. In embodiments of the invention, control 316 is used to synchronize movement of the wafer 320 with the scanning of the charged particle beam across the wafer to keep the charged particle beam at a defined focus on the waver during the scanning. In embodiments of the invention, control 316 synchronizes movement of the wafer with the scanning of the charged particle beam across the wafer by moving the wafer to maintain constant the working distance between the beam emitter and the wafer. Software can be added to allow the stage 304 to move relative to e-beam 336 to keep the working distance w constant.

A further solution is, as mentioned above, to adjust the chuck voltage to adjust for a change in the working distance. The relationship between working distance and the necessary voltage adjustment can be calibrated by beam conditions. For instance, the voltage needed to achieve the desired focus of the e-beam 336 at two or more areas on the wafer, such as, for example, at a near shape in the FOV and at a far shape in the FOV, can be determined, and the voltage needed to achieve the desired focus of the e-beam at other areas of the wafer can be extrapolated from these determined voltages. Software can also be added to adjust the chuck voltage to keep the surface of the wafer in focus to compensate for changes in the working distance.

In embodiments of the invention, detection includes physical defect mode (low beam current), voltage contrast mode (high beam currents) and material contrast mode (high landing energy and high negative Wehnelt plate voltage).

Embodiments of the invention offer solutions for keeping a large field of view (FOV) suitable for e-beam inspection in focus when inspecting a wafer at an angle. For a small FOV like that used for a review SEM (2 um×2 um), when inspecting the wafer at an angle, the working distance from the emitter to the wafer does not change much from the nearest shape in the FOV to the furthest shape in the FOV and the whole FOV is in focus. For a large field of view, such as 60 um×60 um, however, much of the field of view will be out of focus when an angled e-beam is used for inspection. A large FOV is important for inspection because moving the stage takes considerable time. Reducing the number of stage moves increases throughput.

The description of the invention has been presented for purposes of illustration and description, and is not intended to be exhaustive or to limit the invention in the form disclosed. Many modifications and variations will be apparent to those of ordinary skill in the art without departing from the scope of the invention. The embodiments were chosen and described in order to explain the principles and applications of the invention, and to enable others of ordinary skill in the art to understand the invention. The invention may be implemented in various embodiments with various modifications as are suited to a particular contemplated use.

1. A method of inspecting semiconductors, comprising:
directing a charged particle beam onto a semiconductor device at an angle in a range between five degrees and eighty-five degrees from a normal to a top surface of the semiconductor device, wherein secondary and backscattered electrons are transmitted from the semiconductor device;
scanning the charged particle beam across a specified field of the semiconductor device;
adjusting a position of the semiconductor device to maintain the charged particle beam at a defined focus on the semiconductor device while scanning the charged particle beam across the specified field of the semiconductor device;
detecting said secondary and backscattered electrons; and
processing said detected secondary and backscattered electrons to inspect for defined conditions of the semiconductor device.

2. The method according to claim 1, wherein:
the directing the charged particle beam onto a semiconductor device includes emitting the charged particle beam from a beam emitter; and
the adjusting the semiconductor device to maintain the charged particle beam at a defined focus on the semiconductor device includes controlling the position of the semiconductor device relative to the beam emitter to maintain the charged particle beam at the defined focus on the semiconductor device.

3. The method according to claim 2, wherein the controlling the position of the semiconductor device includes maintaining constant a working distance between the beam emitter and the semiconductor device, along the angle at which the charged particle beam is directed onto the semiconductor device.

4. The method according to claim 3, wherein the maintaining constant of the working distance between the beam emitter and the semiconductor device includes moving the semiconductor device vertically to maintain constant of the working distance.

5. The method according to claim 3, wherein the maintaining constant the working distance between the beam emitter and the semiconductor device includes moving the semiconductor device horizontally to maintain constant of the working distance.

6. (canceled)

7. (canceled)

8. The method according to claim 1, wherein the adjusting the semiconductor device to maintain the charged particle beam at a defined focus on the semiconductor device includes adjusting a position of the semiconductor device to compensate for changes in a working distance of the charged particle beam to the semiconductor device caused by the scanning the charged particle beam across the specified field of the semiconductor device.

9. The method according to claim 1, wherein the semiconductor device includes a plurality of parallel fins, the fins have a given height and are spaced apart a given distance, and the directing a charged particle beam onto a semiconductor device at an angle includes determining said angle based on said given height and said given distance.

10. The method according to claim 1, wherein the semiconductor device includes a plurality of fins linearly extending in a given direction on the semiconductor device, and the scanning the charged particle beam across a specified field of the semiconductor device includes inspecting the fins in a direction orthogonal to said given direction of the fins on the semiconductor device.

11. A semiconductor inspection system, comprising:
a stage for holding a semiconductor device;
a stage support to move the stage within a defined range of positions;
a beam emitter to direct a charged particle beam onto the semiconductor device at an angle in a range between five degrees and eighty-five degrees from a normal to a top surface of the semiconductor device;
a detector to detect secondary and backscattered electrons transmitted from the semiconductor device;
a processing system to process said detected secondary and backscattered electrons to inspect for defined conditions of the semiconductor device; and
a control system for controlling the beam emitter to scan the charged particle beam across a specified field of the semiconductor device, and for adjusting a position of the semiconductor device to maintain the charged particle beam at a defined focus on the semiconductor device while scanning the charged particle beam across the specified field of the semiconductor device.

12. The semiconductor inspection system according to claim 11, wherein the control system controls the position of the semiconductor device relative to the beam emitter to maintain the charged particle beam at the defined focus on the semiconductor device.

13. The semiconductor inspection system according to claim 12, wherein the control system synchronizes movement of the semiconductor device with the scanning of the charged particle beam across the specified field of the semiconductor device to keep the charged particle beam at the defined focus on the semiconductor device during said scanning.

14. The semiconductor inspection system according to claim 13, wherein the control system synchronizes movement of the semiconductor device with the scanning of the charged particle beam across the specified field of the semiconductor device by moving the semiconductor device to maintain constant a working distance between the beam emitter and the semiconductor device.

15. The semiconductor inspection system according to claim 11, wherein the control system maintains the charged particle beam at the defined focus on the semiconductor device by adjusting a position of the semiconductor device to compensate for changes in a working distance of the charged particle beam to the semiconductor device caused by the scanning the charged particle beam across the specified field of the semiconductor device.

16. A method of inspecting semiconductors, comprising:
positioning a semiconductor device on a movable stage;
positioning a beam emitter to emit a charged particle beam onto the semiconductor device at an angle, in a range between five degrees and eighty-five degrees, from a normal to a top surface of the semiconductor device;
scanning the charged particle beam across a specified field of the semiconductor device;
detecting secondary and backscattered electrons transmitted from the semiconductor device;
processing said detected secondary and backscattered electrons to inspect for defined conditions of the semiconductor device; and
controlling movement of the movable stage to maintain of a specified spatial relationship between the beam emitter and the semiconductor device to keep the charged particle beam at a defined focus on the semiconductor device while scanning the charged particle beam across the specified field of the semiconductor device.

17. The method according to claim 16, wherein the controlling movement of the movable stage includes maintaining constant of a working distance between the beam emitter and the semiconductor device, along the angle at which the charged particle beam is directed onto the semiconductor device.

18. The method according to claim 16, wherein the controlling movement of the stage support includes adjusting a specified horizontal offset between the beam emitter and the semiconductor device.

19. The method according to claim 16, wherein the semiconductor device includes a plurality of parallel fins, the fins have a given height and are spaced apart a given distance, and the positioning the beam emitter at an angle in a range between five degrees and eighty-five degrees from a normal to a top surface of the semiconductor device includes determining said angle based on said given height and said given distance.

20. The method according to claim 19, wherein the plurality of fins extend longitudinally in a given direction on the semiconductor device, and the directing the charged particle beam onto the semiconductor device at said angle includes inspecting the fins in a direction orthogonal to the given direction on the semiconductor device.
